(19) United States
(12) Patent Application Publication
(10) Pub. No.: US 2026/0265911 A1
(43) Pub. Date: Sep. 10, 2026

(54) PROCESS REACTOR AND METHOD FOR PRODUCING STRUCTURES ON A SUBSTRATE

(71) Applicant: Stephan Wege, Bannewitz-Cunnersdorf (DE)

(72) Inventor: Stephan Wege, Bannewitz-Cunnersdorf (DE)

(21) Appl. No.: 19/165,353

(22) PCT Filed: Mar. 18, 2024
(86) PCT No.: PCT/DE2024/100223

§ 371 Date: Sep. 17, 2025

(30) Foreign Application Priority Data
Mar. 17, 2023 (DE) 10 2023 106 821.0

(51) Int. Cl. C23C 16/455; C23C 16/458; C23C 16/503; C23C 16/52; H01J 37/32; H10P 50/20

(52) U.S. Cl. CPC C23C 16/45544; C23C 16/45536; C23C 16/4558; C23C 16/4586; C23C 16/503; C23C 16/52; H01J 37/32165; H01J 37/3244; H01J 37/32568; H01J 2237/332; H01J 2237/334; H10P 50/20

(57) ABSTRACT

A process reactor (10) serves for the production of structures on a substrate (12) by means of plasma etching with atomic precision and/or plasma-assisted deposition of atomic layers. The process reactor (10) includes a reaction chamber (16), a table (18) and/or a holder for the substrate (12) in the reaction chamber (16). A gas supply (31) evenly wets the substrate (12) with gas in the reaction chamber (16), with the gas supply (31) consisting of a gas injector (32) including a conduit ring (34) with nozzles. The substrate (12) to be processed can be arranged centrally in the conduit ring (34). A pump (60) evacuates the reaction chamber (16). A method serves for producing structures on a substrate in a process reactor.

### CROSS-REFERENCE TO RELATED APPLICATION

This application is a national stage application, filed under 35 U.S.C. § 371, of International Patent Application PCT/DE2024/100223, filed on Mar. 18, 2024, which claims the benefit of German Patent Application DE 10 2023 106 821.0, filed on Mar. 17, 2023.

### TECHNICAL FIELD

The disclosure relates to a process reactor for the production of structures on a substrate by means of plasma etching with atomic accuracy and/or plasma-supported Deposition of atomic layers. The disclosure also relates to a process for the production of structures on a substrate in a process reactor

### BACKGROUND

Process reactors are used in plasma etching technology (ALE) and in plasma-supported deposition (PEALD) of individual atomic layers on a substrate. During deposition, the individual atomic layers are applied to the substrate, such as, for example, a semiconductor, with the ALD (=atomic layer disposition) or with the PEALD method (=plasma enhanced ALD). As a result, smallest structures or dopings on a substrate as are required in industrial chip production.

In PEALD technology, the substrate reacts in a sequential sequence with suitable reactants, also called “precursor”. The sequential sequence allows precise control of the layer thickness of the atomic layers.

The PEALD method can be described in a simplified manner as follows: First, the cleaned Surface of the substrate in the reaction chamber of the process reactor is exposed to a first reactant (usually without plasma). The substrate is often a disk-shaped semiconductor, which is also refer red to as a wafer. It is necessary here that the adsorption on the surface is controlled by a self-limiting process. The choice of the suitable precursor (reaction partner) is crucial. It is thus avoided that no more than one monolayer of the first reactant, regardless of the amount of gas offered, is adsorbed. The residues of the first reactant are then flushed out of the reaction chamber of the process reactor or pumped out with a pump. This prevents a gas phase reaction with a second reactant. The latter is passed over the substrate surface in a further step and reacted with thermal energy in the classic ALD. Subsequently, a so-called flushing cycle is again required in the process reactor.

The reactivity of the reactants with the substrate can be significantly increased by using a plasma. The plasma is produced by, for example, the interaction of an alternating electrical field in a system, for example capacitively coupled.

In this process, it is desirable that the reactants can react with the substrate as uniform or even as possible in terms of time and space. The PEALD plant technology is naturally complex because the gas-guiding and other flow-dynamic systems must also correspond to the uniform coupling of RF power (RF=Radio (high) frequency).

The etching of atomic layers ALE (=Atomic Layer Etching) is a technique that removes single atomic layers. In this case, a sequence is used between as self-limiting chemical modification steps as possible, which relate only to the uppermost atomic layer of the substrate. Furthermore, etching steps are carried out which relate only to the chemically modified regions by using ions with suitably dosed ion energy. This Process requires a complex gas handling (inlet and pumping) for removal rates of an atomic layer.

For PEALD deposition and ALE etching in a process reactor, the flow dynamics is an important parameter, in particular for the required uniformity. Thus, the gas must be introduced as uniformly and symmetrically as possible into the reaction chamber of the process reactor.

Different process reactors are used for plasma etching (ALE) and plasma-assisted deposition (PEALD). The integration of plasma etching technology (ALE) and plasma-assisted deposition (PEALD) in a process reactor, the implementation of both processes in a single process reactor can make the production process of semiconductors much more efficient. However, the technical challenge of combining both processes in a reactor due to their different requirements for process conditions and gas conduction has hit her to prevented implementation.

DE 10 2016 108 845 A1 discloses a gas injector for such ALD, PEALD or ALE process reactors known. The gas injector is designed as an annular base body, inlet nozzles for the gas being arranged symmetrically to the center pointing in the base body. The inlet nozzles are charged with gas individually or in groups via gas inlets. For this purpose, at least one bypass is provided in order to bring the ga s to the inlet nozzles in a uniform manner. As a result, the reaction region in which the substrate is arranged is brought into contact with the reactant in a temporally and spatially uniform manner.

EP 0552 491 BI relates to a plasma etching process using high frequency Plasma processing reactors. In particular, a plasma reactor is described which uses a high-frequency (HF) energy source to electromagnetically couple the associated electromagnetic HF waves to the plasma, a silicon source being in contact with the plasma. Processes are carried out in such a reactor.

DE 10 2020 107 215 A1 describes a method for processing a semiconductor wafer. The method comprises charging a semiconductor wafer onto an upper surface of a wafer 5 clamping device. The method further comprises feeding a gaseous material between the semiconductor wafer and the upper surface of the wafer clamping device through a first gas inlet opening and a second gas inlet opening, which are arranged below a fan-shaped section of the upper surface. The met hod further comprises feeding a fluid medium into a fluid inlet opening of the wafer clamping devi e, and guiding the fluid medium from the fluid inlet opening so that it flows through a plurality of arc-shaped channels which are arranged below the fan-shaped section of the upper surface. In addition, the method comprises feeding a plasma gas via the semiconductor wafer.

DE 10 2019 001 615 A1 introduces a plasma-assisted CVD method in which the energy for generating the plasma is not coupled into the CVD reactor by electromagnetic radiation, but is released by an explosion process of energy which ultimately generates the plasma. As a result, a plasma with layer-forming and growth-promoting reaction species is produced within the explosion zone, said plasma striking the substrate surface by means of the impact front propagating from the explosion site, w here the thin layer to be deposited is formed. The advantage of such a method is a layer deposition within a very short period of time. However, uniform deposition on a substrate cannot be achieved well with this method.

DE 11 2014 005 386 B4 relates to a gas deposition system which is designed to carry out plasma-activated atomic layer deposition (PEALD) gas deposition cycles which can be used to deposit thin-film material layers on exposed surfaces of a solid-state substrate. The PEALD system contains in particular a reaction chamber, a main vacuum pump for producing a first Vacuum pressure in the reaction chamber during non-plasma precursor deposition cycles and a second vacuum pump for producing a second 30 lower vacuum pressure in the reaction chamber during plasma precursor deposition cycles.

WO 2007/042017 A1 relates to a device and a method for the plasma treatment of objects. The device comprises a plasma chamber in which at least one electrode is arranged as an object carrier. Furthermore, at least one wall region of the plasma chamber and/or at least one component arranged in the plasma chamber forms a counter electrode. By means of a high-frequency unit, a plasma in the plasma chamber is formed by applying a high-frequency alternating voltage between the electrode and the counter electrode producible. The plasma chamber is divided by a separating device into at least two subvolumes, of which a first subvolume for a reactive gas contains the electrode and a second subvolume for an inert gas contains a region of the counter electrode which is active in plasma generation.

The separating device is designed in such a way that it allows an electron exchange in the plasma required for generating the plasma between the partial volumes and can act as a diffusion barrier for the reactive gas. The device and the associated method can be used to reduce precipitation on the counterelectrode caused by the plasma treatment.

The known ALD, PEALD and ALE systems have the disadvantage that the substrates to be treated do not come in uniform contact with their reactant via their surface. The reason is an unequal distribution of the respectively reacting gas in the reaction chamber.

Furthermore, a process reactor is known from WO 2023/147814 A1 which serves for plasma etching with atomic accuracy (ALE) and/or plasma-assisted deposition (PEALD) of atomic layers on a substrate. It comprises a rotationally symmetrical reaction chamber, a centrally positioned table or holder for the substrate Gas supply for uniform wetting of the substrate with gas, a pump for evacuating the chamber and means for generating plasma. The described embodiment is distinguished by the rotationally symmetrical arrangement of the reaction chamber and the centrally symmetrical positioning of the pump under the table or the holder.

### SUMMARY

It is an object of the disclosure to avoid the disadvantages of the prior art and to provide a process reactor and a process for an improved and more efficient production of structures on a substrate.

The object is achieved in that a process reactor for the production of structures on a substrate by means of plasma etching with atomic accuracy and/or plasma-assisted deposition of atomic layers of the type mentioned at the outset further comprises the following features:
a) a reaction chamber,
b) a table and/or a holder for the substrate in the reaction chamber,
c) a gas supply which wets the substrate uniformly with gas in the reaction chamber, wherein the gas supply comprises a gas injector which comprises a line ring with nozzles in which the substrate to be processed can be arranged centrally;
d) a pump for evacuating the reaction chamber.
e) a first and a second frequency generator for generating high-frequency voltages;
f) a first and a second electrode for generating a high-frequency electrical alternating field for ionizing gas for generating a plasma,
   wherein the first electrode has the first frequency generator high voltages of a first frequency and of the second frequency generator with high voltages of a second frequency can be acted upon
   wherein the second electrode is grounded
so that the plasma can be generated in a controlled manner with controllable ion energy.

A particularly advantageous aspect is the integration of two frequency generators in a process reactor. These frequency generators enable a generated plasma to be controlled and modulated in a targeted manner by different Frequencies are used for the ionization of gases. Depending on requirements, high voltages with a first frequency or a second frequency can be applied to the first electrode. The proposed process reactor also makes it possible to connect a high voltage with a further frequency to an already applied high voltage with a specific frequency, so that simultaneously high voltages of different frequency are applied to the first electrode. This leads to precise control over ion acceleration, plasma density and electron temperature, which in turn leads to efficient, uniform and controlled deposition or etching on an atomic plane on the substrate. This targeted manipulation of the plasma also enables materials having different chemical and physical properties to be processed efficiently and precisely, which extends the versatility and application width of the process reactor.

The grounded second electrode also contributes in particular to the stabilization of the plasma, which improves the process reliability and the quality of the end products.

Another particularly advantageous aspect is that the design and the possibility of individual adaptation of the process reactor to different process requirements can be carried out both plasma etchings with atomic accuracy and plasma-assisted deposition of atomic layers into one and the same process reactor. This allows (automatized) sequential processing of a substrate with the above-mentioned methods without the substrate in different process reactors must be introduced. This is to be regarded as an essential departure from the prior art in which hitherto different process reactors had to be used for plasma etching and plasma assisted deposition.

In a preferred embodiment of the process reactor, the first frequency comprises a low frequency and the second frequency comprises a high frequency. The low frequency corresponds to a value selected from the range comprising: 400 kHz to 5 MHz. The low frequency preferably corresponds to a value of 2 MHz. In contrast, the high frequency corresponds to a value selected from the range comprising: 40 MHz to 150 MHz.

Preferably, the high frequency corresponds to a value of 60 MHz. The low frequency serves, in particular, for ion acceleration and the high frequency serves, in contrast, preferably for plasma density and electron temperature. The aforementioned value ranges have been shown to be particularly effective. The selection has not been taken by chance, but rather is based on long-term research work on the process reactor.

In a further preferred embodiment of the process reactor, the table and/or the holder comprises the first electrode or is configured as such. About further, a chamber wall and/or a cover preferably comprises the second electrode or is configured as such. This embodiment advantageously enables efficient use of the spatial arrangement of the process reactor, in this respect the embodiment allows a compact construction. In addition integration of the electrodes into structural components of the reactor such as the table or the chamber walls simplifies the construction of the reactor and increase its reliability, since fewer separate components are required and the overall construction becomes more robust.

For the purposes of the disclosure, a cover relates to the upper cover of the reaction chamber. In the above-mentioned embodiment, the cover can function as a second electrode or contain such, which means that it is directly involved in the generation and control of the plasma within the chamber. The chamber wall refers in particular to the lateral boundaries of the reaction chamber of the process re actor. Like the cover, the chamber wall can serve as a second electrode or contain such.

In a further preferred embodiment, the first and second electrodes are in the form of plates lying substantially parallel to one another. This configuration enables a very uniform distribution of the plasma within the reaction chamber, since the electrode arrangement and design supports a homogeneous electrical field distribution. This leads to a more uniform treatment of the substrate, improves the uniformity of etching or coating and reduces potential defects or inhomogeneities on the processed substrate. The spacing of the plates should be selected as small as possible, preferably in the range from Imm to 10 mm. A distance of 3 mm proves to be particularly suitable. As a result, the re action space with the plasma is kept small, which considerably accelerates the exchange of the reaction gases or the result is cleaning gases.

In a further preferred embodiment, the reaction chamber is rotationally symmetrical or cylindrical, wherein the cover and the table and/or the holder preferably form the plates lying parallel to one another. The rotationally symmetrical or cylindrical configuration of the reaction chamber permits a uniform distribution of the reaction medium, which leads to a homogeneous reaction condition within the chamber. The interaction of rotational symmetry of the reaction chamber and the centrally arranged pump ensures uniform flow in the area of the surface of the substrate during operation of the plant. The pump is arranged below the table and/or the holder. In this way it is possible to ensure uniform and uniform flow even during evacuation in the reaction chamber.

In a further preferred embodiment, the process reactor comprises a control unit, wherein the control unit is configured to control and/or regulate the gas supply, the pump and the frequency generators in such a way that a switching of plasma etching with atomic accuracy to plasma-supported deposition of atomic layers, and vice versa, can take place without further manual adaptation of the process reactor. The integration of a control unit allows automated process control and adaptation to different proc ess requirements. The ability to switch between plasma etching and plasma-assisted deposition without manual adjustments increases the flexibility and efficiency of the process reactor in different applications.

In the context of this application, a control unit is primarily understood as a functional unit which can monitor, regulate and control the production process. This unit can be modular in order to enable flexible adaptation to various control tasks. The control unit preferably has a data processing unit which i s equipped with a processor, memory, sensors and/or communication means.

In a further preferred embodiment, the nozzles included in the line ring are designed as Laval nozzles. The design of the nozzles as Laval nozzles enables efficient acceleration of the gas, resulting in improved gas dynamics and reaction kinetics in Process leads. Laval nozzles can also preferably increase the uniformity of the gas flow, which contributes to a more uniform treatment of the substrate surface and thus to a higher quality of the end products.

In a further preferred embodiment, the line ring comprises a plurality of gas lines. The inclusion of several gas lines in the line ring allows simultaneous or sequential supply of different gases. A separate guidance of the gases can also contribute to improved control of the gas composition and concentration, which increases the precision of the chemical processes in the reactor. In particular the gas supply or the line ring is configured to introduce process gases, such as, for example, 0 2, N2, HBr, Cl, 142, Cl-la, CHF3, C4F8, C4F6, SF6, NF3 into the reaction chamber. The proc ess gases can also be introduced into the reaction chamber as dilute gas mixtures.

The substrate preferably comprises a silicon wafer, a gallium nitride wafer, a quartz wafer or a galli um arsenide wafer. The gallium nitride wafer and the gallium arsenide wafer are preferably used in combination with aluminum. The use of different substrate types such as silicon wafers, gallium nitride wafers, quartz wafers or Gallium arsenide wafer enables a wide applicability of the process reactor for different semiconductor materials and thus high flexibility in semiconductor production.

In a further preferred embodiment, the table and/or the holder has a constant first temperature. In contrast, a chamber wall and/or covers a constant second temperature. The chamber wall preferably has a first temperature of 900, while the table preferably has a second temperature from a range of −500 C to 1500 C.

In a further preferred embodiment, the disclosure relates to a method for producing structures o n a substrate in a process reactor according to one of the preceding embodiments, wherein the method comprises the following steps:
a.) introducing a substrate into a reaction chamber of the process reactor; and
b.) performing plasma etching with atomic accuracy on the substrate in the reaction chamber;
c.) or Implementation of plasma-assisted deposition of atomic layers on a substrate in the reaction chamber; or
d.) successive passage of plasma etching with atomic accuracy and plasma-assisted deposition of atomic layers on the substrate in the reaction chamber,
   where the sequence of successive processes can vary, and
   the change of plasma etching with atomic accuracy to plasma-assisted deposition of atomic layers, and vice versa, takes place without further manual adaptation of the process reactor.

The possibility of carrying out plasma etching with atomic accuracy and plasma-assisted deposition of atomic layers either separately or in successive steps in a single process reactor offers a high process flexibility and allows the production of complex structures with precise layer thicknesses. The automated change between plasma etching and deposition without manual adjustments reduces the process time and minimizes the risk of contamination or errors, which leads to a higher yield and cost efficiency.

A person skilled in the art recognizes that the process reactor discussed advantages, technical effects and preferred embodiments apply analogously to the process for the production of structures on a substrate. All ad vantages, technical effects and preferred embodiments described in the context of the process can also be transferred to the process reactor.

In a further preferred embodiment, the method is characterized in that, that in the course of the plasma etching with atomic accuracy and the plasma-assisted deposition of atomic layers in each case at least one gas is introduced into the reaction chamber via a gas supply, wherein the gas supply consists of a gas injector comprising a line ring with nozzles. The use of a gas injector with a line ring and nozzles enable a uniform and uniform distribution of the gases in the reaction chamber, which leads to a homogeneous reaction environment and thus to more uniform etching and deposition processes.

The precise gas supply by the gas injector can also improve the efficiency of material consumption and reduce process costs by minimizing gas consumption and increasing process reliability. In addition, a second process chamber (either ALD or AL E) can be saved. This results in advantages, particularly with regard to energy costs and sustain ability.

In a further preferred embodiment, in the course of the plasma etching with atomic accuracy and the plasma-assisted deposition of atomic layers, a plasma is ignited via an electrical alternating fi eld that is generated by two electrodes included in the process reactor,
wherein a first electrode is acted upon by a first frequency generator with high voltages of a first frequency and with high voltages of a second frequency by a second frequency generator;
wherein the second electrode is grounded.

As already discussed in the context of the process reactor, the use of two different frequencies enables a differentiated control of the plasma properties, whereby a more precise adaptation to the specific requirements of the etching or deposition process is achieved. In particular, a very precise control of the ion energy, regardless of plasma density and average electron temperature, is made possible for the kinetic reaction.

In a further preferred embodiment, the plasma etching is carried out with atomic accuracy such that
the substrate is wetted uniformly with an etching gas via the gas supply, wherein the substrate to be processed is arranged centrally in the line ring;
an inert gas is introduced via the gas feed into the reaction chamber in order to rinse excess etching gas and to purify the reaction chamber;
high-frequency electric alternating field for generating a plasma provided;
the reaction chamber is evacuated via a pump.

The uniform and as uniform as possible uniform wetting of the substrate with etching gas lead s to a homogeneous etching rate over the entire substrate surface, which results in uniformity and quality of the processed structures improved. The etching gas can be in pure form or as a gas mixture. The introduction of an inert gas for rinsing excess etching gas and for cleaning the reaction chamber minimizes impurities and defects on the substrate. By evacuating the reaction chamber by means of a pump, a controlled pressure environment is created and a low pressure is ensured throughout the entire process. This increases process stability and reproducibility and maintain a stable plasma.

In a further preferred embodiment, the plasma-supported deposition of atomic layers takes place such that
the substrate is wetted uniformly with a gas mixture, which in part compromises a precursor gas, via the gas feed, wherein the substrate to be processed is arranged centrally in the line ring;
a high-frequency electric alternating field for generating a plasmas provided;
a reaction gas, such as, for example, 02, H2, N2, HCL, CL2, HBr, NF3, S F6, CF4, C4F6, C4F8, CHF3, Cl-la, is introduced into the reaction chamber via the gas supply,
an inert gas is introduced into the reaction chamber via the gas feed, excess precursor gas and/or all reaction products and undesired rinse gases and clean the reaction chamber
the reaction chamber is evacuated via a pump.

The uniform wetting of the substrate with a gas mixture which contains a precursor gas makes possible, in particular, a homogeneous deposition of material layers, which leads to an improved layer quality and uniform layer thicknesses. evacuating the reaction chamber via a pump and rinsing the reaction chamber with a inert gas leads to an effect already described in the course of the plasma etching. It is understood that the reaction gases can also be introduced into the reaction chamber diluted as a gas mixture. In contrast, the precursor gas can also be introduced into the reaction chamber as a pure gas in order to wet the substrate.

In a further preferred embodiment, the plasma etching with atomic accuracy and the plasma-supported deposition of atomic layers is interposed by the following method step: an inert gas is introduced by a gas supply. The interposition of an inert gas after plasma etching (or after deposition) and before the deposition of atomic layers (or before plasma etching) prevents undesirable chemical reactions and contaminations. The introduction of an inert gas contributes to the stabilization of the reaction conditions by serving as a buffer between the individual proc ess steps and thus improving the process control.

In a further preferred embodiment, the individual method steps of the plasma etching are carried out with atomic accuracy and the plasma-assisted deposition of atomic layers are automated via a control unit, wherein the control unit is based on algorithms of artificial intelligence. The implementation of artificial intelligence algorithms in the controller enables adaptive process control, which can adapt to variable operating conditions in real time, which leads to increased efficiency and precision of the method. By using artificial intelligence, the method can integrate self-learning mechanisms that enable continuous optimization of the process parameters, thereby improving product quality and reducing reject rates.

Further embodiments and advantages result from the subject matter of the subclaims and the drawings with the associated descriptions. Exemplary embodiments are explained in more detail below with reference to the attached drawings. In addition, spatially relative terms, such as “below”, “below”, “lower”, “top”, “upper” and the like, can be used in the present text in order to simplify the description in order to describe the relationship of an element or structural element to one or more other elements or structural elements, as illustrated in the figures. The spatially relative terms are intended to be Orientation comprises further orientations of the device during use or operation. The apparatus can also be oriented differently (rotated or otherwise aligned) and the spatial relative descriptors used in the present text can be interpreted equally accordingly.

The invention is not intended to be limited to these listed exemplary embodiments alone. They merely serve to explain the invention in more detail. In addition, the content of the cited publications is made to the disclosure content of the present application.

### BRIEF DESCRIPTION OF THE DRAWINGS

FIG. 1 shows a schematic diagram of a vertical cross-section through a preferred embodiment of the process reactor.

FIG. 2 shows a schematic diagram of a horizontal cross-section through a preferred embodiment of the process reactor.

FIG. 3 shows a flow diagram of a preferred embodiment of the method for producing structures on a substrate in a process reactor.

FIG. 4 shows a flow diagram of a preferred embodiment of atomic-precision plasma etching.

FIG. 5 shows a flow diagram of a preferred embodiment of plasma-assisted atomic layer deposition.

### DETAILED DESCRIPTION

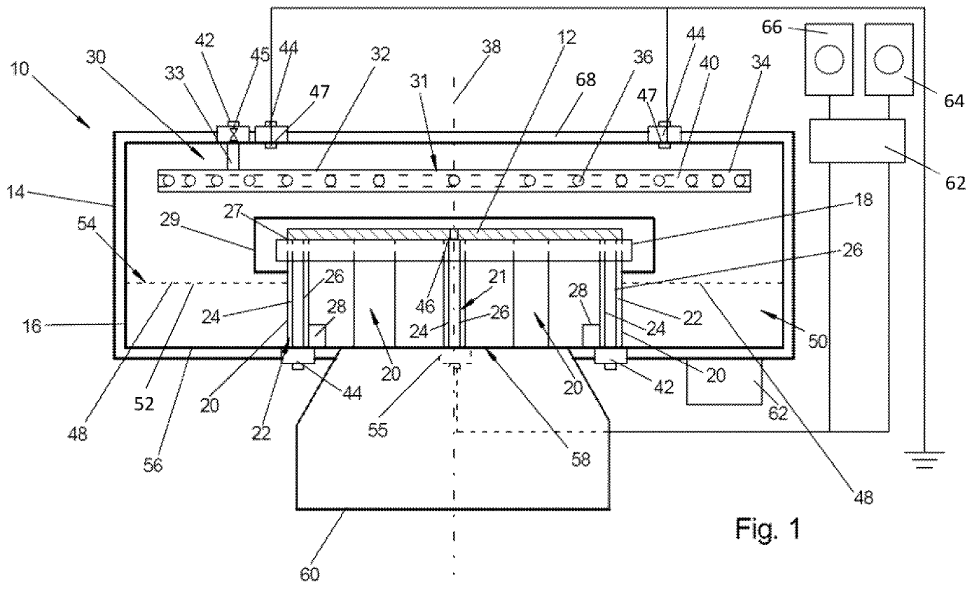

FIG. 1 schematically shows a schematic diagram of the vertical section of a process reactor 10 for plasma etching with atomic accuracy of a substrate 12 and/or for plasma-assisted deposition of atomic layers on the substrate 12. In this embodiment, the process reactor 10 contains a protective housing 14, in which a reaction chamber 16 is provided. While the protective ho using 14 is almost the reaction chamber 16 is configured to be rotationally symmetrical.

In the present exemplary embodiment, reaction chamber 16 is substantially cylindrical. In principle, other rotationally symmetrical geometries of the reaction chamber 16 are also conceivable, for example a conical or spherical reaction chamber 16. The substrate 12 is held centrally in a reaction chamber 16 on a table 18. The table 18 is supported by six tubular shaped bodies 20.

The tubular profile bodies 20 are hollow in the core, whereby a cavity 22 is formed in them. Supply and control lines 21, both supply lines 24 and discharge lines 26, are guided from the reaction chamber 16 through the cavity 22 of the tubular profile bodies 20. The feed lines 24 and discharge lines 26 are, for example, required electrical lines, liquid lines or gas lines. These supply lines 21 are guided through passages 27 in the table 18. In this way, resources can be fed centrally and symmetrically to the substrate 12 from outside the reaction chamber 16. The tubular profile bodies 20 are designed to be height-adjustable. This is realized by a telescopic structure of the tubular profile bodies 20, which can change their length by means of a drive 28.

The substrate 12 is introduced into the reaction chamber 16 via a vacuum lock 29 and is centrally positioned and fixed on the table 18 (also called “chuck”). By means of the vacuum lock 29, the finished processed substrate 12 is also removed from the reaction chamber 16 again.

Gas supply 31 is provided in the reaction chamber 16 of the process reactor 10 in the upper region. The gas supply 31 is configured as a gas injector 32. From outside the reaction chamber 16, a gas or a gas is introduced through a gas line 33 gas or mixed gas to the gas injector 32. The gas injector 32 consists of a line ring 34 on which numerous Laval nozzles 36 are arranged. The center of the annular gas injectors 32 lie on a central axis 38 of reaction chamber 16. The Laval nozzles 36 are arranged radially symmetrically about the central axis 38. In this embodiment, the Laval nozzles 36 show the central axis 38 of the reaction chamber 16. To produce a uniform and symmetrical distribution of the reaction gas on the Laval nozzles 36, at least one channel is provided as a bypass 40 to the line ring 34.

Connections 42, 44 serve for connecting the gas line 33, such as for helium, and electrical supply and control lines 21 to the process reactor 10. The amount of gas fed into the gas injector 32 can b e regulated via a controllable control valve 45.

In addition, the process reactor has a first and a second electrode 46, 47 to generating a high-frequency electric alternating field for the ionization of gas for generating a plasma. The reactivity of the reactants with the substrate 12 is significantly increased when a plasm a is used. The plasma is produced by igniting a gas discharge. Particularly suitable plasma gas is argon for the reaction processes. A sequential sequence is achieved by pulsed plasma power.

The second electrode 47 is grounded. In contrast, the first electrode 46 is charged with high-frequency high voltage, in particular via connection 55 and via electrical feed lines 24. In this connection, a first and a second frequency generator 64, 66 are provided for generating high-frequency voltages, wherein the first electrode 46 can be charged by the first frequency generator 64 with high voltages of a first frequency and with high voltages of a second frequency by the second frequency generator 66.

It is preferably provided that high voltages of the first frequency applied to the first electrode 4 6 can be switched to high voltages of the second frequency, and vice versa, so that high voltages of the first and second frequency are simultaneously applied to the first electrode 46.

The proposed process reactor 10 is also distinguished, inter alia, in that the first frequency comprises a low frequency and the second frequency comprises a high frequency. The low frequency can correspond to a value from the range from 400 kHz to 5 MHz. While the high frequency can correspond to a value from the range 40 MHz to 150 MHz.

The table 18 comprises the first electrode 46 or can be configured as such. On the other hand, the cover 68 of the process reactor 10 has the second electrode 4.

Furthermore, the process reactor 10 has a control unit 62. The control unit 62 can be divided into individual separate processor-controlled modules which perform different tasks. In particular, the control unit 62 is configured to control and/or regulate the gas supply 31, the pump 60 and the frequency generators 64, 66 in such a way that a switching of plasma etchings with atomic accuracy to plasma-assisted deposition of atomic layers, and vice versa, without further manual adaptation of the process reactor 10.

A ring-shaped dynamic-pressure generator 48 is provided in the lower region 50, below the table 18. The dynamic pressure generator 48 is an annular sieve 54, whereby a grounded metal ring with numerous narrow-mesh bores 52 is understood, through which a gas can be evacuated. The dynamic pressure generator 48 serves as a dynamic pressure generator for the gas present in the reaction chamber 16 and simultaneously limits the extent of the plasma produced in the reaction chamber 16. The dynamic pressure generator 48 thus also acts as a plasma limiter. Moreover, the lower region 50 is decoupled from the upper region 30 as far as possible in terms of flow by the dynamic pressure generator 48.

The reaction chamber 16 has a central opening 58 at its bottom 56. A turbopump 60 is flanged centrally symmetrically to this central opening 58. The power of the turbopump 60 is regulated by a processor-controlled control unit 62. The turbo pump 60 serves to evacuate the reaction chamber 16. The turbopump 60 ensures that the reaction chamber 16 operates permanently in the low-pressure region.

The rotationally symmetrical reaction chamber 16 and the correspondingly symmetrical arrangements of the components for the gas supply and evacuation of the gas as interaction partners for the substrate 12 allow an extremely uniform flow distribution in the region of the centrally symmetrically arranged substrate 12. This desired uniform distribution results in an equally uniform reaction of the gas as a reactant with the substrate 12.

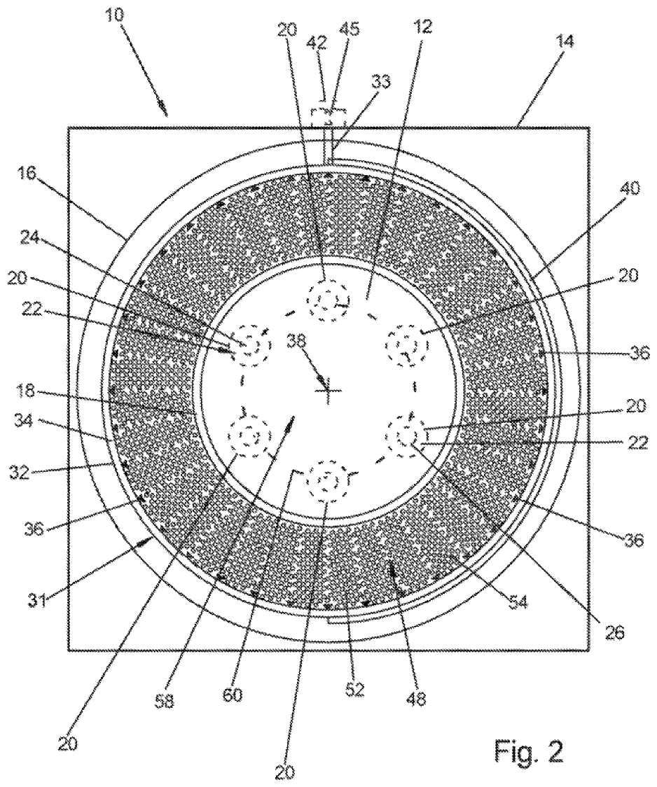

FIG. 2 shows, as a schematic diagram, a horizontal section through the process reactor 10 according to FIG. 1. Insofar as the components of the two figures correspond, the same reference numerals are also used. As is very clear in this illustration of FIG. 2, the components are arranged rotationally symmetrically about the central axis 38. The reaction chamber 16 is provided in the protective housing 14.

In the reaction chamber 16, the gas injector 32 is arranged centered around the axis 38. Laval nozzle s 36 are provided on the line ring 34. A part of the laval nozzles 36 is acted upon by gas on the one h and by the line ring 34 and on the other hand by the bypass 40. In the present exemplary embodiment, gas injector 32 is charged with a gas or a gas mixture as a reactant by the individual gas feed line 33, which is connected to the gas connection 42. The amount of gas which is conducted via the gas connection 42 to the gas injector 32 is regulated by the control valve 45.

The table 18, on which the substrate 12 is fixed, is supported by the six tubular profile bodies 20. Both the table 18 and Chuck as well as the substrate 12 are positioned centrally in the reaction chamber 16 below the gas injector 32. The profile bodies 20 are likewise arranged radially symmetrically about the axis 38. The feed lines 24 and possibly also discharge lines 26 are guided through the profile bodies 20. The feed lines 24 are gas lines through which, for example, the gas helium is transported or electrical lines via which the first electrode 46 is supplied with high voltage. If necessary, these lines are sufficiently strongly insulated by the high voltage in order to avoid electrical breakdowns. Not yet heating elements shown are supplied with voltage via such feed lines 24. The discharge lines 26 may be, for example, signal lines via which signals are transmitted by sensors or control signals (not shown) for various components.

In this horizontal sectional view, the mashine-like structure of the stagnation pressure generator 48. The stagnation pressure generator 48 is formed by the earthed metallic annular screen 54 with its bores 52. The stagnation pressure generator 48 also prevents an undesired expansion of the plasma. As a result of the dynamic pressure generated by the dynamic pressure generator 48 for a gas or gas mixture to be evacuated, the uniformity of the flow in the upper area 30 optimized. As the flow below the dynamic pressure generator 48 behaves, it is largely negligible for the reaction of the substrate 12 with a gas as a reactant.

The turbopump 60 evacuates the reaction chamber 16. Due to the central symmetry arranging the turbopump 60 on the bottom 56 of the reaction chamber 16, the gas or gas mixture symmetrically sucked through the central opening 58 into the turbopump 60. Da i are the radial-symmetrical flow profiles of the gas or Gas mixture all about the same, thereby an optimized uniformity of the flow profiles in the area of the substrate 12 can be substantially guaranteed. The symmetrical flow profiles are only achieved by the radially symmetrical arrangements of the components, and by the rotationally symmetrical reaction chamber 16 and the centrally symmetrically fastened turbo pump 60 are achieved.

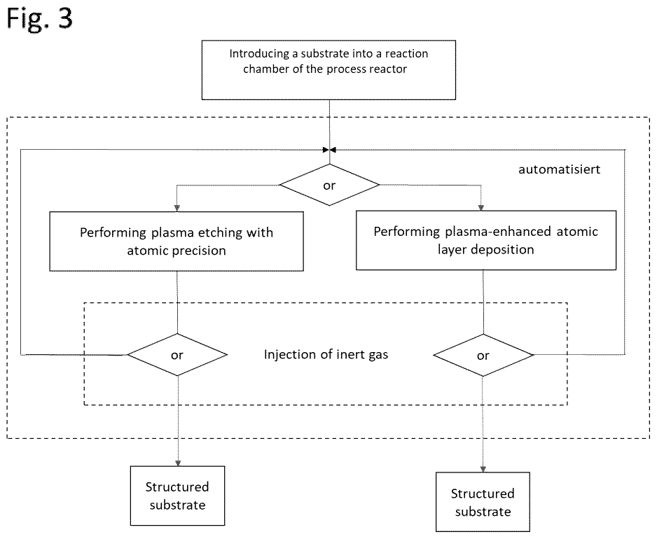

FIG. 3 shows a flow diagram of a preferred embodiment of the method for producing structures on a substrate 12 in a process reactor 10, which comprises the following steps:

A substrate 12 is introduced into a reaction chamber 16 of the process reactor 10. The substrate 12 can then either be subjected to a plasma etching process with atomic accuracy, or a plasma-assist ed deposition of atomic layers onto the substrate 12 can take place. It is also possible to carry out these two processes successively, wherein the sequence of the processes can vary. In particular, inert gas is introduced between the plasma etching and the deposition of atomic layers by a gas supply in order to purify the reaction chamber 16.

The change between plasma etching and plasma-assisted deposition of atomic layers takes place automatically without further manual adaptation of the process reactor 10.

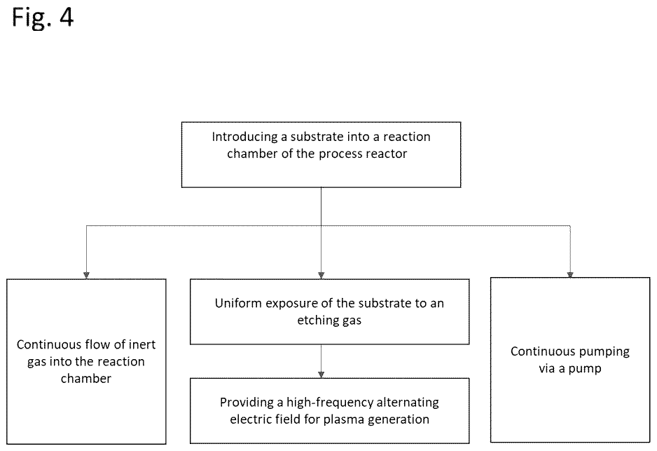

FIG. 4 shows a flow diagram of a preferred embodiment of the plasma etching with atomic accuracy. In a first step, a substrate 12 is introduced into the reaction chamber of the process react or 10. Subsequently, the substrate 12 is wetted uniformly with an etching gas via a gas supply 31. Here, the substrate 12 to be processed is located centrally in the line ring 34.

An inert gas is introduced into the reaction chamber 16 via the gas feed 31, in particular in order to rinse excess etching gas and to purify the reaction chamber 16. The inert gas is introduced continuously into the reaction chamber 16. In addition, a high-frequency electrical alternating field is provided in order to generate a plasma. In addition, the reaction chamber 16 is continuously evacuated by means of a pump 60.

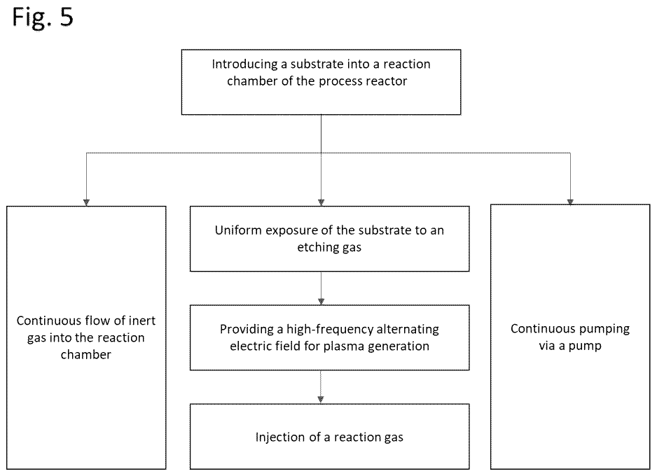

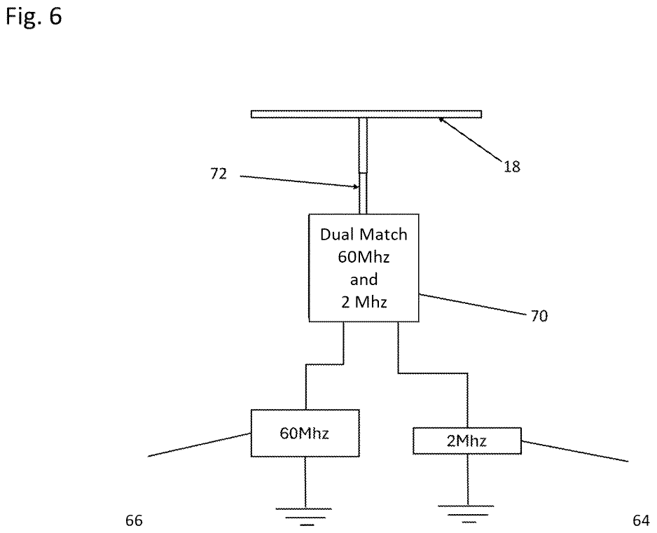

FIG. 5 shows a flow diagram of a preferred embodiment of the plasma-supported deposition of atomic layers. In a first step, a substrate 12 comes into the reaction chamber 16 of process reactor 10. Subsequently, the substrate 12 is uniformly wetted with a gas mixture which contains in proportion a precursor gas. This takes place via a gas feed 31, and the substrate 12 to be processed is positioned centrally in the line ring 34.

A high-frequency electric alternating field is provided to generate a plasma. A reaction gas, such as, for example, 02 or 1-12, is introduced into the reaction chamber 16, likewise via the gas feed 31. An inert gas is fed continuously in order to rinse excess precursor gas and/or all reaction products and undesired gases and to purify the reaction chamber 16. In addition, the reaction chamber 16 is continuously evacuated by means of a pump 60.

FIG. 6 shows a schematic representation of the coupling-in of the high-frequency voltages. A multi-frequency tuning device 70 is connected to a first frequency generator 64 and a second frequency generator 66. The first frequency generator 64 is configured to generate high voltages of a high frequency, preferably 60 MHz, while the second frequency generator 66 is set to a lower frequency, preferably 2 MHz. These frequency generators serve to generate a high-frequency electric alternating fi eld which is required for the ionization of gas and the generation of plasma within a reaction chamber (not shown).

The multi-frequency tuning device 70 is connected to the first electrode 64 via a high-frequency supply 72. This is comprised in the table 18 or the table 18 is designed as such. The first electrode 64 can optionally be acted upon by high voltages of the first or second frequency or a combination of both, in order to precisely control the properties of the plasma and to achieve a controllable ion energy.

### REFERENCE NUMERALS

10 Process reactor
12 Substrate
14 Protective housing
16 Reaction chamber
18 Table
20 Tubular profile body
21 Supply and control lines
22 Cavity
24 Feed lines
26 Exhaust lines
27 Passages
28 Drive
29 Vacuum lock
30 Upper region
31 Gas supply
32 Gas injector
33 Gas line
34 Conduit ring
36 Laval nozzles
38 Central axis
40 Bypass channel
42 Gas connection
44 Connection
45 Adjustable control valve
46 First electrode
47 Second electrode
48 Stagnation pressure generator
50 Lower region
52 Boreholes
54 Annular sieve
55 Connection
56 Bottom
58 Central opening
60 Pump/turbomolecular pump
62 Control unit
64 First frequency generator
66 Second frequency generator
68 Cover
70 Multi-frequency tuning device
72 High-frequency feed

1.-27. (canceled)

28. A process reactor (10) for producing structures on a substrate (12) by atomic-precision plasma etching and/or plasma-assisted atomic layer deposition, comprising:
a reaction chamber (16);
a table (18) and/or a support for the substrate (12) in the reaction chamber (16);
a gas supply (31) configured to uniformly wet the substrate (12) with gas in the reaction chamber (16), the gas supply (31) comprising a gas injector (32) including a conduit ring (34) with nozzles, in which the substrate (12) to be processed can be arranged centrally;
a pump (60) for evacuating the reaction chamber (16);
a first frequency generator (64) and a second frequency generator (66) for generating high-frequency high voltages; and
a first electrode (46) and a second electrode (47) for generating a high-frequency electric alternating field for ionizing gas to generate a plasma,
wherein the first electrode (46) can be energized with high voltages of a first frequency from the first frequency generator (64) and with high voltages of a second frequency from the second frequency generator (66), and
wherein the second electrode (47) is grounded,
such that the plasma can be generated in a controlled manner with controllable ion energy.

29. The process reactor (10) according to claim 28,
wherein the high voltages of the second frequency are switchable in addition to the high voltages of the first frequency applied to the first electrode (46), and vice versa, so that high voltages of the first and second frequency are present simultaneously on the first electrode (46).

30. The process reactor (10) according to claim 28,
wherein the first frequency comprises a low frequency and the second frequency comprises a high frequency,
wherein the low frequency corresponds to a value selected from a range of 400 kHz to 5 MHz, and
wherein the high frequency corresponds to a value selected from a range of 40 MHz to 150 MHz.

31. The process reactor (10) according to claim 28,
wherein the table (18) and/or the support comprises or is configured as the first electrode (46); and
wherein a chamber wall and/or a lid (68) comprises or is configured as the second electrode (47).

32. The process reactor (10) according to claim 31,
wherein the first electrode (46) and the second electrode (47) are configured as parallel plates which lie essentially parallel to one another.

33. The process reactor (10) according to claim 32,
wherein the reaction chamber (16) is rotationally symmetrical or cylindrical, the lid (68) and the table (18) and/or the support forming the parallel plates.

34. The process reactor (10) according to claim 28,
wherein the pump (60) is arranged centrally beneath the table (18) and/or the support at the reaction chamber (16).

35. The process reactor (10) according to claim 28, further comprising
a control unit (62), the control unit (62) being configured to control and/or regulate the gas supply (31), the pump (60) and the frequency generators (64, 66) such that switching from atomic-precision plasma etching to plasma-assisted atomic layer deposition, and vice versa, can be carried out without further manual adjustment of the process reactor (10).

36. The process reactor (10) according to claim 28,
wherein the nozzles included in the conduit ring (34) are formed as Laval nozzles (36).

37. The process reactor (10) according to claim 28,
wherein the conduit ring (34) comprises a plurality of gas lines.

38. The process reactor (10) according to claim 28,
wherein the substrate (12) comprises a silicon wafer, a gallium nitride wafer, a quartz wafer or a gallium arsenide wafer.

39. The process reactor (10) according to claim 28,
wherein the gas supply (31) is configured to introduce process gases selected from the group consisting of O₂, N₂, HBr, Cl₂, I₂, Cl-14, CHF₃, C₄F₈, C₄F₆, SF₆ and NF₃, into the reaction chamber (16).

40. The process reactor (10) according to claim 28,
wherein the table (18) and/or the support exhibits a constant first temperature and a chamber wall and/or a lid (68) exhibits a constant second temperature.

41. A method for producing structures on a substrate (12), the method comprising:
providing the process reactor as in claim 28;
introducing a substrate (12) into a reaction chamber (16) of the process reactor (10); and
performing atomic-precision plasma etching on the substrate (12) in the reaction chamber (16), or
performing plasma-assisted atomic layer deposition on the substrate (12) in the reaction chamber (16), or
sequentially performing atomic-precision plasma etching and plasma-assisted atomic layer deposition on the substrate (12) in the reaction chamber (16),
wherein an order of the sequentially performed processes may vary, and
wherein switching from atomic-precision plasma etching to plasma-assisted atomic layer deposition, and vice versa, can be carried out without any further manual adjustment of the process reactor (10).

42. The method according to claim 41,
wherein during both the atomic-precision plasma etching and the plasma-assisted atomic layer deposition at least one gas is introduced into the reaction chamber via the gas supply (31), the gas supply (31) comprising a gas injector (32) including a conduit ring (34) with nozzles.

43. The method according to claim 41,
wherein during the atomic-precision plasma etching and the plasma-assisted atomic layer deposition a plasma is ignited by an electric alternating field generated by two electrodes (46, 47) comprised in the process reactor (10).

44. The method according to claim 43, wherein
either high voltages of the second frequency are switched in addition to the high voltages of the first frequency applied to the first electrode (46), or
high voltages of the first frequency are switched in addition to the high voltages of the second frequency applied to the first electrode (46), such that high voltages of the first and second frequencies are applied simultaneously to the first electrode (46).

45. The method according to claim 43,
wherein the first frequency comprises a low frequency and the second frequency comprises a high frequency,
wherein the low frequency is selected from a range of 400 kHz to 5 MHz,
wherein the high frequency is selected from a range of 40 MHz to 150 MHz.

46. The method according to claim 45,
wherein the low frequency serves for ion acceleration and the high frequency serves for controlling plasma density and electron temperature.

47. The method according to claim 41,
wherein atomic-precision plasma etching is carried out such that:
the substrate (12) is uniformly wetted with an etching gas via the gas supply (31), the substrate being centrally arranged in the conduit ring (34);
an inert gas is introduced via the gas supply (31) into the reaction chamber (16) to purge excess etching gas and clean the chamber;
a high-frequency electric alternating field is provided to generate a plasma; and
the reaction chamber (16) is evacuated by a pump (60).

48. The method according to claim 41,
wherein plasma-assisted atomic layer deposition is carried out such that:
the substrate (12) is uniformly wetted with a gas mixture containing a precursor gas via the gas supply (31), the substrate being centrally arranged in the conduit ring (34);
a high-frequency electric alternating field is provided to generate a plasma;
a reaction gas, such as O₂, H₂, N₂, HCl, Cl₂, HBr, NF₃, SF₆, CF₄, C₄F₆, C₄F₈, CHF₃ or CH₄, is introduced into the reaction chamber (16) via the gas supply (31);
an inert gas is introduced via the gas supply (31) to purge excess precursor gas and/or reaction products and clean the chamber; and
the reaction chamber (16) is evacuated by a pump (60).

49. The method according to claim 41,
wherein between the atomic-precision plasma etching and the plasma-assisted atomic layer deposition,
an inert gas introduction step is interposed via the gas supply.

50. The method according to claim 41,
wherein the substrate (12) comprises a silicon wafer, a gallium nitride wafer, a quartz wafer or a gallium arsenide wafer.

51. The method according to claim 41,
wherein the table (18) and/or the support are tempered to a constant first temperature and a chamber wall is tempered to a constant second temperature.

52. The method according to claim 41,
wherein the individual process steps of atomic-precision plasma etching and plasma-assisted atomic layer deposition are automated via a control unit (62).

53. The method according to claim 52,
wherein the control is based on artificial intelligence algorithms.

54. A method, comprising:
using the process reactor (10) according to claim 28 for producing structures on a substrate (12).
